(19) United States
(12) Patent Application Publication
(10) Pub. No.: US 2013/0319856 A1
(43) Pub. Date: Dec. 5, 2013

(54) Method for Manufacturing Target Material for Copper Lead of TFT-LCD Array Substrate and Target Material

(71) Applicant: Hao Kou, Shenzhen (CN)

(72) Inventor: Hao Kou, Shenzhen (CN)

(73) Assignee: Shenzhen China Star Optoelectronics Technology Co., LTD., Shenzhen City, Guangdong (CN)

(21) Appl. No.: 13/635,392

(22) PCT Filed: Jun. 7, 2012
(86) PCT No.: PCT/CN12/76546

§ 371 Date: Sep. 14, 2012

(30) Foreign Application Priority Data
May 30, 2012 (CN) 201210174287.0

(51) Int. Cl. C23C 14/34; B22F 3/105

(52) U.S. Cl. CPC C23C 14/3407; B22F 3/105
USPC 204/298.13; 419/1

(57) ABSTRACT

The present invention relates to a method for manufacturing target material for copper lead of TFT-LCD array substrate and a target material. The method includes (1) providing copper powder and a spark plasma activated sintering device; and (2) placing the copper powder in the spark plasma activated sintering device for sintering to obtain a target material for manufacturing copper lead of TFT-LCD array substrate. The method for manufacturing target material for copper lead of TFT-LCD array substrate according to the present invention uses a spark plasma activated sintering device to sinter copper power for forming a target material. The process is simple and efficiency is high. Also, the orientation of crystalline plane of the target material can be effectively controlled to improve the performance of the target material, whereby a copper lead manufactured with such a target material shows low electrical resistivity, low film stress, and low surface roughness.

### BACKGROUND OF THE INVENTION

1. Field of the Invention

The present invention relates to the field of sputtering target, and in particular to a method for manufacturing target material for a copper lead of a TFT-LCD (Thin-Film Transistor Liquid Crystal Display) array substrate and a target material.

2. The Related Arts

Liquid crystal display (LCD) has a variety of advantages, such as thin device body, low power consumption, and being free of radiation, and is thus widely used. Most of the LCDs that are currently available in the market are backlighting LCDs, which comprise a liquid crystal display panel and a backlight module. The working principle of the liquid crystal display panel is that liquid crystal molecules are interposed between two parallel glass substrates and a plurality of vertical and horizontal fine electrical wires is arranged between the two glass substrates, whereby the liquid crystal molecules are controlled to change direction by application of electricity in order to refract light emitting from the backlight module for generating images.

Generally, a liquid crystal display panel is composed of a color filter (CF) substrate, a thin-film transistor (TFT) substrate, and liquid crystal (LC) contained between the CF substrate and the TFT substrate. Thin-film transistors are formed on the TFT substrate. In the manufacturing process of the thin-film transistor, metal layers are often formed with sputtering process, of which the principle is a process in which charged particles are applied to bombard a target material and when the accelerated ions bombard a surface of solid, collision of surface atoms occur and transfer of energy and momentum happens so that target material atoms escape from the surface and get deposited on a backing material.

Metal leads used in a thin-film transistor is generally formed by sputtering an aluminum (Al) lead target material to form an aluminum film, followed by a masking operation. Yet, with the trend and requirement that a display terminal, such as a liquid crystal display, gets increasingly large size and high definition and the driving frequency gets high, the display panel manufacturers start to use copper (Cu) lead target material that is of low electrical resistivity (around 2 μΩ cm) to replace the aluminum lead target material that is of high electrical resistivity (around 4 μΩ cm) to handle the resistance/capacitance delay issue found in the TFT array system.

Referring to FIGS. 1-3, the electrical resistivity of copper is greatly affected by orientation of crystalline plane and crystal grain size. For copper that is of a face-centered cubic (FCC) structure, it shows the densest arrangement in the crystalline plane (111). A metal film formed with sputtering of such a copper target material tends to be located on the crystalline plane (111) to more prominently show relative low electrical resistivity, smaller film stress, and lower surface roughness.

The currently adopted target material manufacturing process is sequentially sintering, shaping through hot rolling/hot extrusion, annealing to recover crystallization, and machine processing. Such a process cannot easily control orientation of grain in the steps of shaping through hot rolling/hot extrusion and annealing to recover crystallization so that it is hard to select the orientation of the crystalline plane (111) in making a Cu film. Referring to FIG. 4, which is a picture showing surface roughness of a copper film manufactured by sputtering copper target material that is manufactured with a regular process, the surface roughness is Ra=2.73 nm, which is relatively high and is thus disadvantageous for improving quality of a TFT-LCD array substrate.

### SUMMARY OF THE INVENTION

An object of the present invention is to provide a method for manufacturing target material for a copper lead of a TFT-LCD array substrate, whereby a copper film made with a target material manufactured with the method is relatively low electrical resistivity, relatively small film stress, and relatively low surface roughness, and the process is simple and efficiency is high.

Another object of the present invention is to provide a target material, which shows relatively high density and low oxygen content and thus facilitates manufacturing of a copper lead of a TFT-LCD array substrate.

To achieve the objects, the present invention provides a method for manufacturing target material for a copper lead of a TFT-LCD array substrate, which comprises the following steps:

Step 1: providing copper powder and a spark plasma activated sintering device; and

Step 2: placing the copper powder in the spark plasma activated sintering device for sintering to obtain a target material for manufacturing a copper lead of a TFT-LCD array substrate.

Mass of the copper powder is calculated according to predetermined surface area and thickness of a copper film to be formed with sputtering operation.

In Step 2, the sintering temperature is 400-550° C. and the sintering time is 3-5 minutes.

The sintering temperature is 480° C. and the sintering time is 3 minutes.

Purity of the copper powder is 99.99%.

The present invention also provides a target material, which is used to manufacture a copper lead of a TFT-LCD array substrate and is formed by placing copper powder in a spark plasma activated sintering device to carry out sintering.

The target material has a relative density that is greater than or equal to 99.5% and oxygen content that is less than or equal to 50 ppm.

Purity of the copper powder is 99.99%.

The sintering temperature of the copper powder sintered in the spark plasma activated sintering device is 400-550° C. and the sintering time is 3-5 minutes.

The sintering temperature is 480° C. and the sintering time is 3 minutes.

The efficacy of the present invention is that the present invention provides a method for manufacturing target material for a copper lead of a TFT-LCD array substrate that uses a spark plasma activated sintering device to sinter copper power for forming a target material. The process is simple and efficiency is high. Also, the orientation of crystalline plane of the target material can be effectively controlled to improve the performance of the target material, whereby a copper lead manufactured with such a target material shows low electrical resistivity, low film stress, and low surface roughness. The present invention provides a target material that is formed by sintering copper powder with a spark plasma activated sintering device and shows relatively high density and low oxygen content and thus facilitates manufacturing of a copper lead of a TFT-LCD array substrate.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, will be apparent from the following detailed description of an embodiment of the present invention, with reference to the attached drawings. In the drawings:

FIG. 1 is a diagram showing distribution of peak intensity of diffraction for copper;

FIG. 2 is a schematic view showing crystalline plane (111) formed in face-centered cubic lattice cells of copper;

FIG. 3 is a schematic view showing the face-centered cubic (FCC) crystal structure of the crystalline plane (111) of FIG. 2;

FIG. 4 is a picture showing surface roughness of a copper film manufactured by sputtering copper target material that is manufactured with a regular process;

FIGS. 5 is a flow chart showing a method for manufacturing target material for a copper lead of a TFT-LCD array substrate according to the present invention;

FIG. 6 is a diagram showing comparison of diffraction peaks between the copper target material manufactured with the method for manufacturing target material for a copper lead of a TFT-LCD array substrate according to the present invention and the copper target material manufactured with a conventional method;

FIG. 7 is a plot showing the relationship between sputtering speed for manufacturing copper film with the copper target material manufactured with the method for manufacturing target material for a copper lead of a TFT-LCD array substrate according to the present invention and orientated grain rate on crystalline plane (111); and

FIG. 8 is a picture showing surface roughness of a copper film formed through sputtering of the copper target material manufactured with the present invention.

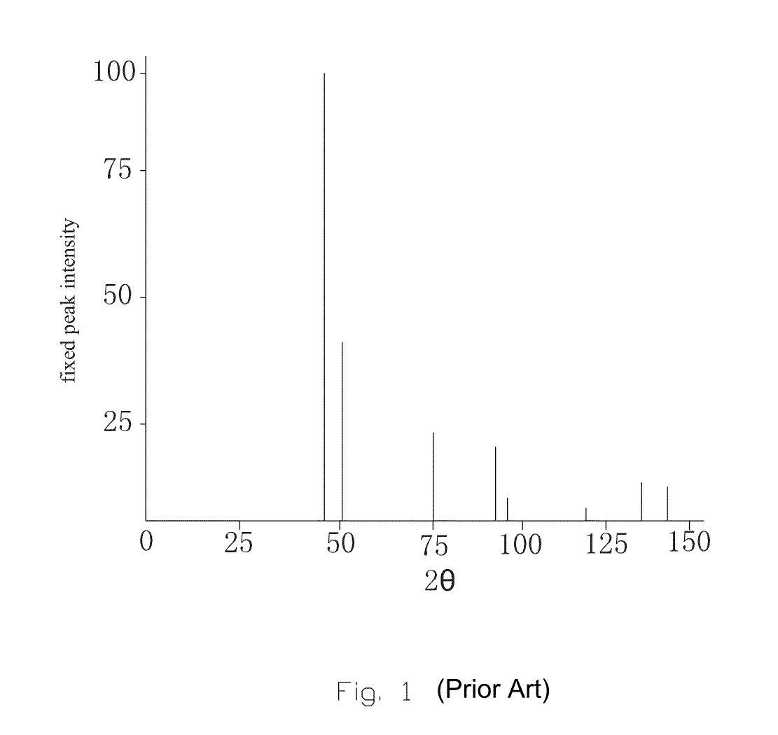

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

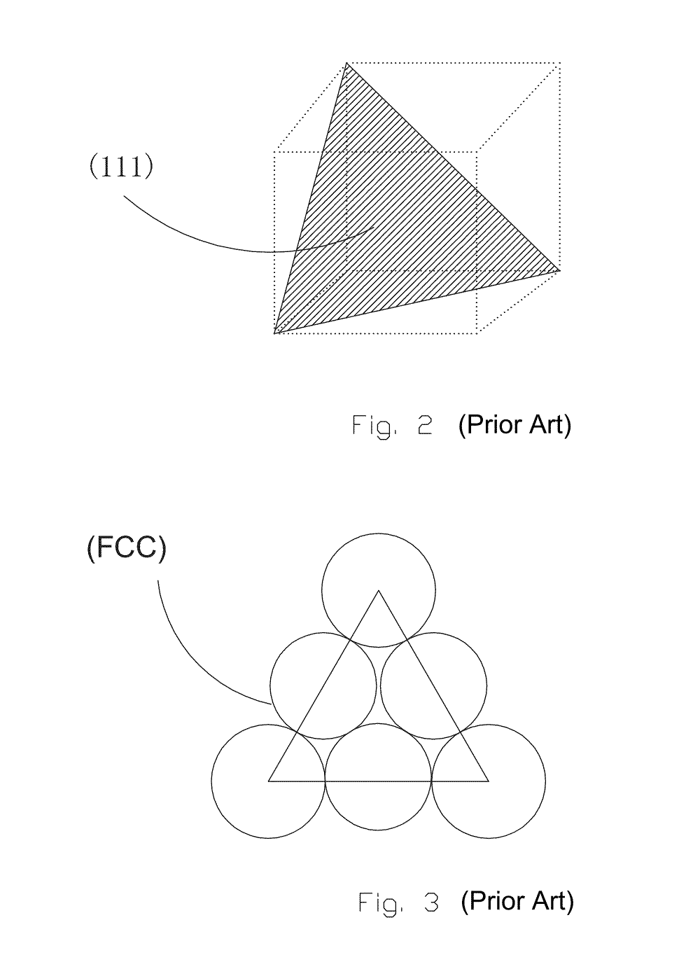

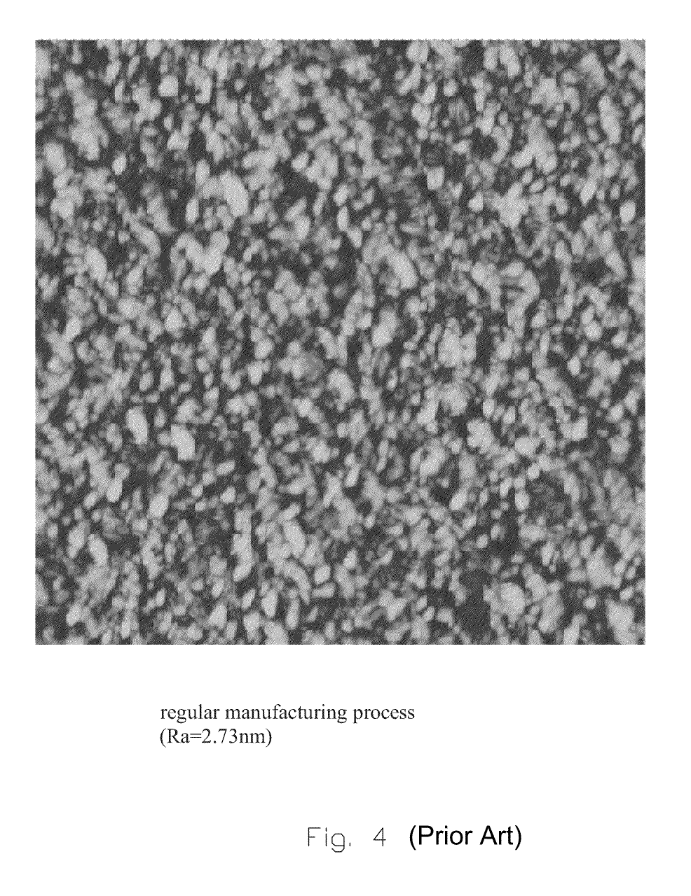

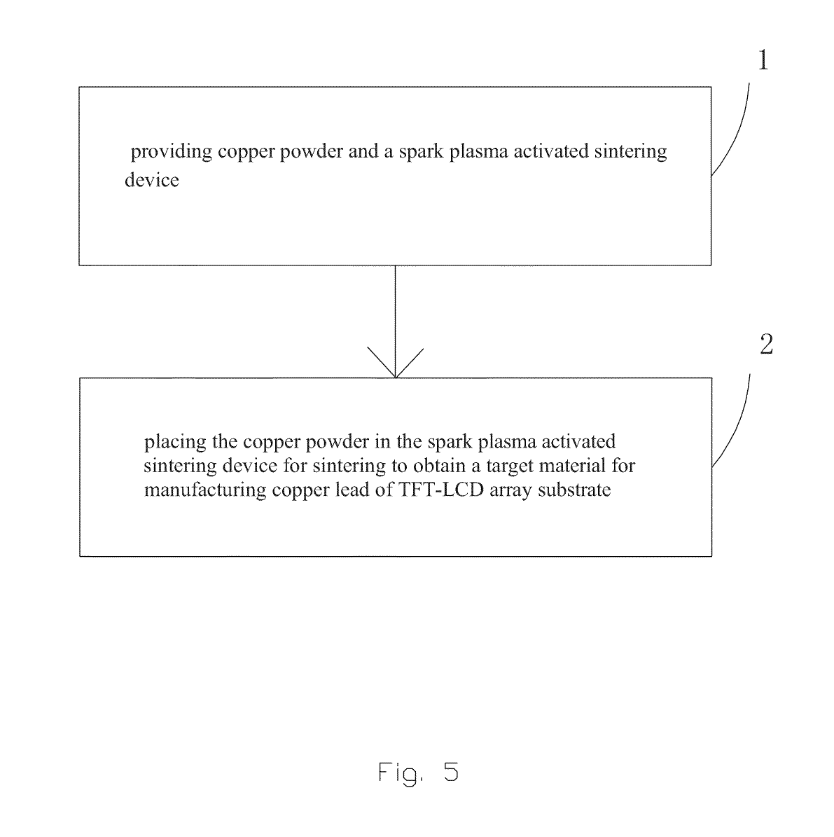

Referring to FIGS. 2-6, the present invention provides a method for manufacturing target material for a copper lead of a TFT-LCD (Thin-Film Transistor Liquid Crystal Display). The method comprises the following steps:

Step 1: providing copper powder and a spark plasma activated sintering device.

The mass of the copper powder can be calculated according to the predetermined surface area and thickness of a copper film to be formed with sputtering operation. The purity of the copper powder can be determined according to the properties of the copper film to be formed. In the instant embodiment, the purity of the copper powder is 99.99%.

Step 2: placing the copper powder in the spark plasma activated sintering device for sintering to obtain a target material for manufacturing a copper lead of a TFT-LCD array substrate.

The spark plasma activated sintering device discharges a high voltage at the electrodes thereof during a sintering process to instantaneously excite a portion of the copper into plasma. Since the copper powder that is in sintering is set in an excited state, the sintering temperature can be lowered and the sintering time shortened. The sintering temperature is 400-550° C. and the sintering time is 3-5 minutes. In the instant embodiment, the sintering temperature is 480° C. and the sintering time is 3 minutes.

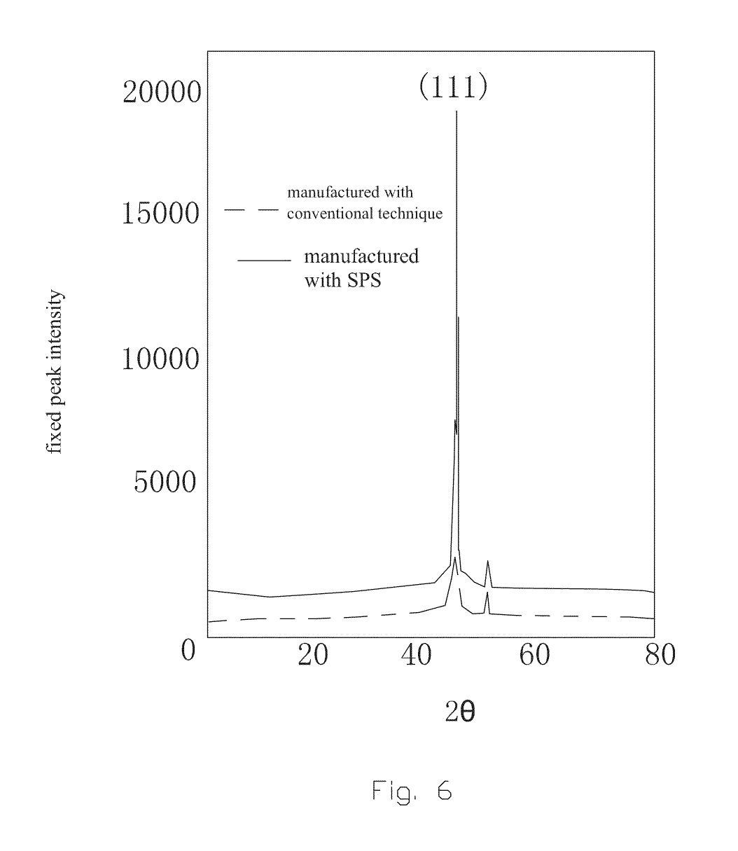

Referring to FIGS. 3 and 6, compared to the known techniques, the method for manufacturing target material for a copper lead of a TFT-LCD array substrate according to the present invention makes copper crystallized on the crystalline plane (111) of the lowest cohesive energy according to its characteristics of face-centered cubic (FCC) crystalline structure, so that the target material manufactured with the present invention, after being subjected to sputtering to form a copper film, can be subsequently subjected to masking operation to form copper leads that are of relatively low electrical resistivity, relatively small film stress, and relatively low surface roughness.

Since the present invention uses copper powder to carry out sintering, subsequent processing may thus be omitted thereby avoiding the accompanying texture generated by machine processing such as cutting and thus lowering down the manufacturing cost.

The method for manufacturing target material for a copper lead of a TFT-LCD array substrate according to the present invention uses a spark plasma activated sintering device to sinter copper power for forming a target material. The process is simple and efficiency is high. Also, the orientation of crystalline plane of the target material can be effectively controlled to improve the performance of the target material, whereby a copper lead manufactured with such a target material shows low electrical resistivity, low film stress, and low surface roughness.

The present invention also provides a target material for manufacturing copper leads of a TFT-LCD array substrate and being formed by placing copper powder in a spark plasma activated sintering device to carry out sintering. The relative density of the target material is greater than or equal to 99.5% and oxygen content is less than or equal to 50 ppm.

The copper powder has purity of 99.99% and is sintered in the spark plasma activated sintering device at a sintering temperature of 400-550° C. for a period of sintering time of 3-5 minutes. Preferably, the sintering temperature that the copper powder is sintered in the spark plasma activated sintering device is 480° C. and the sintering time is 3 minutes.

Referring to FIGS. 2, 3, and 6, compared to the known techniques, the target material according to the present invention allows the copper to get crystallized on the crystalline plane (111) of the lowest cohesive energy according to its characteristics of face-centered cubic (FCC) crystalline structure, so that the target material manufactured with the present invention, after being subjected to sputtering to form a copper film, can be subsequently subjected to masking operation to form copper leads that are of relatively low electrical resistivity, relatively small film stress, and relatively low surface roughness.

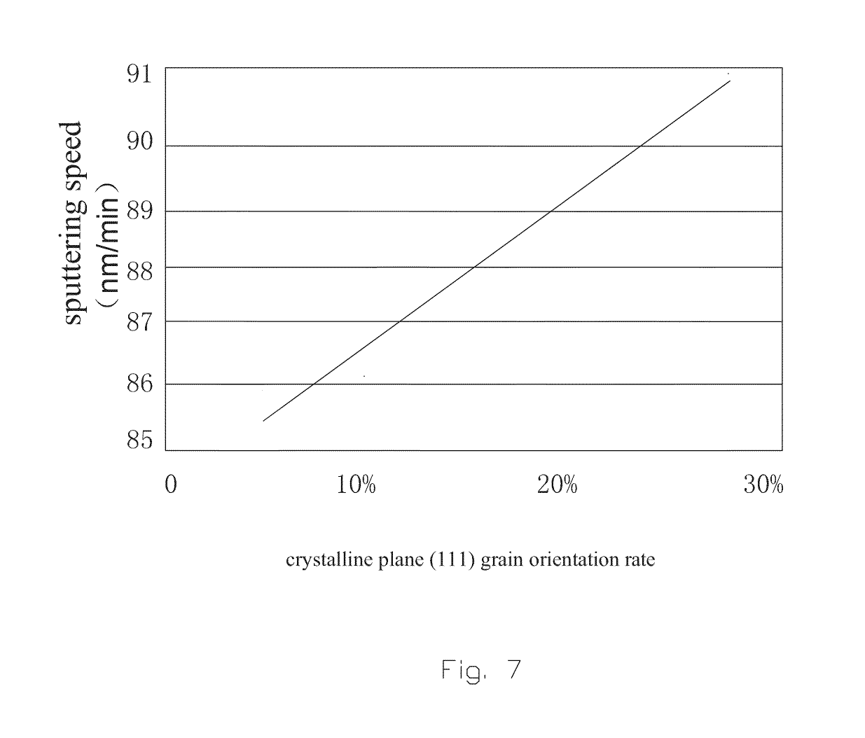

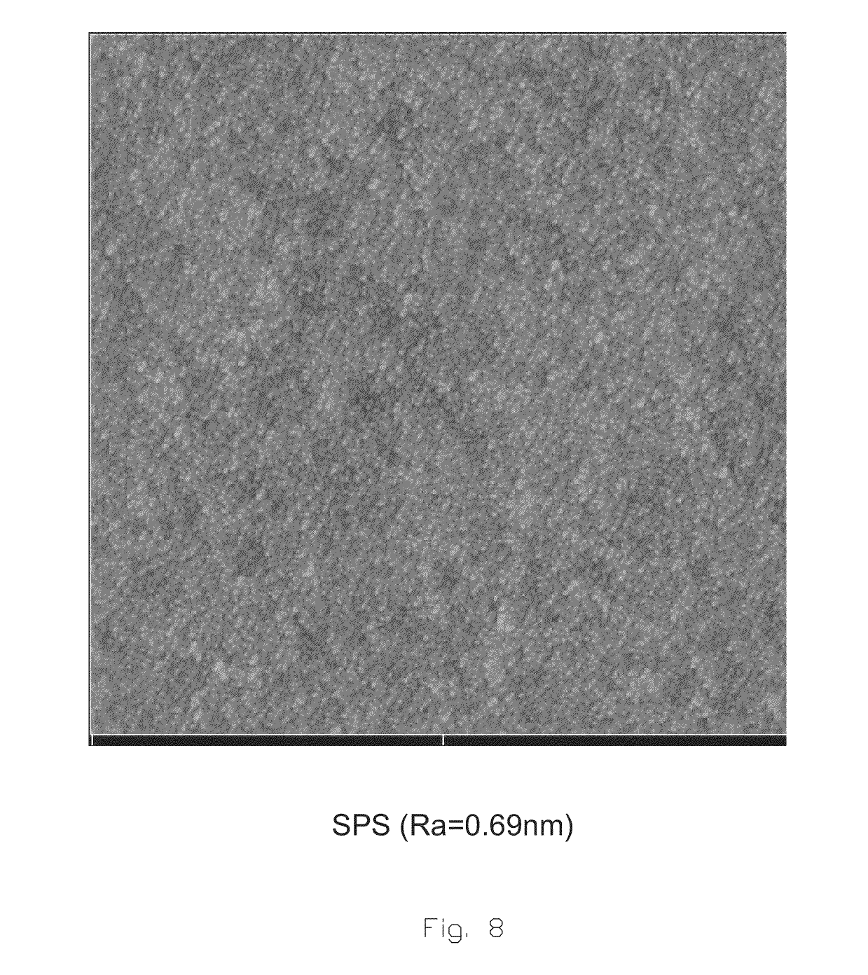

Referring to FIG. 7, the orientated crystallization rate of the target material of the present invention in the crystalline plane (111) is proportional to the sputtering speed. In other words, the higher the orientated crystallization rate of the target material is on the crystalline plane, the greater the speed of forming copper film with sputtering will be.

The method for manufacturing target material for a copper lead of a TFT-LCD array substrate according to the present invention makes copper crystallized on the crystalline plane (111) of the lowest cohesive energy according to its characteristics of face-centered cubic (FCC) crystalline structure, so that the orientated crystallization rate of target material on the crystalline plane (111) is enhanced to thereby facilitate increasing sputtering speed, shortening manufacturing time, and lowering down manufacturing cost.

Referring to FIG. 8, which is a picture showing surface roughness of a copper film formed through sputtering of the copper target material manufactured with the present invention, when the target material of the present invention is applied in sputtering operation to form a copper film, the surface roughness is Ra=0.69 nm, which, compared to the surface roughness Ra=2.73 nm of a copper film made by sputtering of a target material manufactured with a regular process, is much lower. In other words, the copper film manufactured by sputtering of the target material according to the present invention has a smoother surface and

The target material according to the present invention is formed by sintering copper powder with a spark plasma activated sintering device and shows relatively high density and low oxygen content and thus facilitates manufacturing of copper lead of TFT-LCD array substrate.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for manufacturing target material for a copper lead of a Thin-Film Transistor Liquid Crystal Display (TFT-LCD) array substrate, comprising the following steps:
(1) providing copper powder and a spark plasma activated sintering device; and
(2) placing the copper powder in the spark plasma activated sintering device for sintering to obtain a target material for manufacturing copper lead of TFT-LCD array substrate.

2. The method for manufacturing target material for a copper lead of a TFT-LCD array substrate as claimed in claim 1, wherein mass of the copper powder is calculated according to predetermined surface area and thickness of a copper film to be formed with sputtering operation.

3. The method for manufacturing target material for a copper lead of a TFT-LCD array substrate as claimed in claim 1, wherein in step (2), sintering temperature is 400-550° C. and sintering time is 3-5 minutes.

4. The method for manufacturing target material for a copper lead of a TFT-LCD array substrate as claimed in claim 3, wherein the sintering temperature is 480° C. and the sintering time is 3 minutes.

5. The method for manufacturing target material for a copper lead of a TFT-LCD array substrate as claimed in claim 1, wherein purity of the copper powder is 99.99%.

6. A method for manufacturing target material for a copper lead of a Thin-Film Transistor Liquid Crystal Display (TFT-LCD) array substrate, comprising the following steps:
(1) providing copper powder and a spark plasma activated sintering device; and
(2) placing the copper powder in the spark plasma activated sintering device for sintering to obtain a target material for manufacturing copper lead of TFT-LCD array substrate;
wherein mass of the copper powder is calculated according to predetermined surface area and thickness of a copper film to be formed with sputtering operation;
wherein in step (2), sintering temperature is 400-550° C. and sintering time is 3-5 minutes; and
wherein purity of the copper powder is 99.99%.

7. A target material, which is used to manufacture a copper lead of a Thin-Film Transistor Liquid Crystal Display (TFT-LCD) array substrate and is formed by placing copper powder in a spark plasma activated sintering device to carry out sintering.

8. The target material as claimed in claim 7, wherein the target material has a relative density that is greater than or equal to 99.5% and oxygen content that is less than or equal to 50 ppm.

9. The target material as claimed in claim 7, wherein purity of the copper powder is 99.99%.

10. The target material as claimed in claim 7, wherein sintering temperature of the copper powder sintered in the spark plasma activated sintering device is 400-550° C. and sintering time is 3-5 minutes.

11. The target material as claimed in claim 10, wherein the sintering temperature is 480° C. and the sintering time is 3 minutes.
